(19) United States
(12) Patent Application Publication
(10) Pub. No.: US 2007/0145427 A1
(43) Pub. Date: Jun. 28, 2007

(54) SOLID-STATE IMAGE SENSOR

(75) Inventors: Mamoru Arimoto, Ogaki-shi (JP); Hayato Nakashima, Anpachi-cho (JP); Toshio Nakakuki, Mizuho-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 11/614,620

(22) Filed: Dec. 21, 2006

(30) Foreign Application Priority Data
Dec. 26, 2005 (JP) 2005-371825
Nov. 8, 2006 (JP) 2006-303199

(51) Int. Cl. H01L 29/768

(52) U.S. Cl. 257/239

(57) ABSTRACT

A solid-state image sensor capable of suppressing generation of cross talk or a dark current and improving transfer efficiency of electrons (signal charge) can be obtained. This solid-state image sensor includes a plurality of pixels and a transfer gate electrode arranged in each of the plurality of pixels. An OFF-state voltage of the transfer gate electrode located on a boundary part between the pixels during an imaging period is lower than an OFF-state voltage of the transfer gate electrode located on the boundary part between the pixels during a transfer period.

### BACKGROUND OF THE INVENTION

1. Field of the Invention

The present invention relates to a solid-state image sensor, and more particularly, it relates to a solid-state image sensor including a plurality of pixels.

2. Description of the Background Art

In a solid-state image sensor comprising an image area including a plurality of pixels, a structure in which a plurality of transfer gate electrodes are arranged in each of the plurality of pixels is disclosed in Japanese Patent Laying-Open No. 6-311435 (1994). This solid-state image sensor has a structure in which the plurality of transfer gate electrodes are formed above a substrate interposed a gate insulating film therebetween at prescribed intervals respectively.

In a conventional solid-state image sensor, during an imaging period (storage period), a prescribed transfer gate electrode among the plurality of transfer gate electrodes arranged in each pixel is turned on, whereby electrons (signal charge) generated by photoelectric conversion are stored in a potential well formed in a region under each ON-state transfer gate electrode. During the aforementioned imaging period, each transfer gate electrode arranged in the vicinity of a boundary part between the pixels is so controlled as to be turned off, whereby a potential barrier is formed in a region under each OFF-state transfer gate electrode. Thus, it is possible to suppress that electrons generated in other pixel adjacent to a prescribed pixel is mixed into the prescribed pixel. All the transfer gate electrodes are switched between an ON state and an OFF state in prescribed cycles, whereby the electrons stored in each pixel in the aforementioned manner are sequentially transferred by sequentially moving, in a transfer direction (direction perpendicular to a direction in which the transfer gate electrodes extend), the region where the potential well for storing the electrons is formed. In the solid-state image sensor disclosed in Japanese Patent Laying-Open No. 6-311435 (1994), an ON-state voltage and an OFF-state voltage of the transfer gate electrodes in an imaging period and a transfer period are set to +5V and −10V, respectively.

In the solid-state image sensor disclosed in Japanese Patent Laying-Open No. 6-311435 (1994), the OFF-state voltage of −10V having a larger absolute value is applied during the transfer period, whereby holes in the regions under the OFF-state transfer gate electrodes are likely to occur. Therefore, due to recombination of the hole and the electron, transfer efficiency of the electrons is disadvantageously reduced. As means for solving this disadvantage, the absolute value of the OFF-state voltage (−10V) of the transfer gate electrode is made smaller, whereby the amount of the holes generated in the regions under the OFF-state transfer gate electrodes in the transfer period is reduced. Thus, the probability of the recombination of the holes and the electrons is reduced.

In the solid-state image sensor disclosed in Japanese Patent Laying-Open No. 6-311435 (1994), however, in a case where the absolute value of the OFF-state voltage of the transfer gate electrodes is made small, while the amount of the holes generated in the regions under the OFF-state transfer gate electrodes in the transfer period can be reduced, a potential of the region under each OFF-state transfer gate electrode is greater during the imaging period, whereby a height of the potential barriers is reduced. Thus, the electrons generated in other pixel adjacent to a prescribed pixel are disadvantageously likely to get over the potential barrier and be mixed into the prescribed pixel. In addition, in a case where the absolute value of the OFF-state voltage of the transfer gate electrodes in the transfer period is made small, the amount of the holes generated in the regions under the OFF-state transfer gate electrodes (interfaces of the substrate and the gate electrodes) is reduced during the imaging period, whereby the electrodes serving as a dark current are disadvantageously likely to be excited in a conduction band through an interface state. Consequently, in the aforementioned Japanese Patent Laying-Open No. 6-311435 (1994), it is difficult to suppress generation of cross talk or a dark current while improving transfer efficiency of electrons (signal charge).

### SUMMARY OF THE INVENTION

The present invention has been proposed in order to solve the aforementioned problems, and it is an object of the present invention to provide a solid-state image sensor capable of suppressing generation of cross talk or a dark current and improving transfer efficiency of electrons (signal charge).

In order to attain the aforementioned object, a solid-state image sensor according to an aspect of the present invention comprises a plurality of pixels and a transfer gate electrode arranged in each of the plurality of pixels. An OFF-state voltage of the transfer gate electrode located at least in the vicinity of a boundary part between the pixels in an imaging period is lower than an OFF-state voltage of the transfer gate electrode located at least in the vicinity of the boundary part between the pixels in a transfer period. In a case where there exists a transfer gate electrode bridging over the boundary part of the pixels, the transfer gate electrode is the transfer gate electrode located in the vicinity of the boundary part between the pixels of the present invention. In a case where there does not exist a transfer gate electrode bridging over the boundary part of the pixels, at least one transfer gate electrode among two transfer gate electrodes adjacent to the boundary part between the pixels is the transfer gate electrode located in the vicinity of the boundary part between the pixels of the present invention.

In the solid-state image sensor according to this aspect, as hereinabove described, the OFF-state voltage of the transfer gate electrode located at least in the vicinity of the boundary part between the pixels in the imaging period is lower than the OFF-state voltage of the transfer gate electrode located at least in the vicinity of the boundary part between the pixels in a transfer period, whereby a potential of a region under the OFF state transfer gate electrode located in the vicinity of the boundary part between the pixels in the imaging period can be shallower than a potential of the region under the OFF state transfer gate electrode located in the vicinity of the boundary part between the pixels in the transfer period. Thus, the height of the potential barrier of the region under the transfer gate electrode located in the vicinity of the boundary part between the pixels can be increased during the imaging period, whereby it is possible to suppress that electrons (signal charge) generated in other pixel adjacent to a prescribed pixel get over the potential barrier and are mixed into the prescribed pixel during the imaging period. Consequently, generation of cross talk can be suppressed. The OFF-state voltage of the transfer gate electrode in the imaging period is set lower than the OFF-state voltage of the transfer gate electrode in the transfer period, whereby, for example, in a structure in which the transfer gate electrode is formed above a substrate interposed a gate insulating film therebetween, an amount of holes generated in an interface between the substrate and the gate insulating film under the OFF-state transfer gate electrode in the imaging period can be greater than an amount of holes generated in the interface between the substrate and the gate insulating film under the OFF-state transfer gate electrode in the transfer period. Thus, a large number of the holes exist in the interface between the substrate and the gate insulating film under the OFF-state transfer gate electrode during the imaging period, whereby it is possible to suppress that electrons serving as a dark current are excited in the conduction band through the interface state. Consequently, generation of a dark current can be suppressed during the imaging period. The OFF-state voltage of the transfer gate electrode in the imaging period is set lower than the OFF-state voltage of the transfer gate electrode in the transfer period, whereby an amount of the holes generated in the region under the OFF-state transfer gate electrode in the transfer period can be fewer than an amount of the holes generated in the region under the OFF-state transfer gate electrode in the imaging period. Thus, the probability of the recombination of the electrons and the holes can be reduced during the transfer period,-whereby transfer efficiency of the electrons can be improved. Consequently, according to the aspect, generation of cross talk or a dark current can be suppressed, and transfer efficiency of electrons (signal charge) can be improved.

In the solid-state image sensor according to the aforementioned aspect, a position in which a potential well for storing electrons is formed is switched between a region under a prescribed transfer gate electrode and a region under a transfer gate electrode other than the region under the prescribed transfer gate electrode during an imaging period, using at least two transfer gate electrodes among a plurality of the transfer gate electrodes. According to this structure, an averaging procedure can be performed for dark currents generated in the regions under a plurality of the transfer gate electrodes, whereby variation in the dark currents generated in the regions under a plurality of the transfer gate electrodes can be suppressed.

In this case, the position in which the potential well for storing electrons is formed is preferably switched between the region under the prescribed transfer gate electrode and the region under the other transfer gate electrode a plurality of times during the imaging period. According to this structure, variation in the dark currents generated in the regions under a plurality of the transfer gate electrodes can be easily suppressed.

In the solid-state image sensor according to the aforementioned aspect, the transfer gate electrode preferably includes a plurality of first transfer gate electrodes located in the vicinity of the boundary part between the pixels and a second transfer gate electrode so arranged as to be held between the plurality of first transfer gate electrodes, and the plurality of first transfer gate electrodes and the second transfer gate electrode are preferably switched between an ON state and an OFF state during the imaging period. According to this structure, during the imaging period, potential wells for storing electrons can be formed in the regions under the plurality of first transfer gate electrodes and the second transfer gate electrode in the same pixel respectively. Thus, an averaging procedure can be performed for dark currents generated in the regions under the plurality of first transfer gate electrodes and the second transfer gate electrode in the same pixel during the imaging period, whereby variation in the dark currents generated in the regions under the plurality of first transfer gate electrodes and the second transfer gate electrode can be suppressed.

In this case, the plurality of first transfer gate electrodes are preferably so arranged at a prescribed interval as to hold the boundary part of the plurality of pixels therebetween. According to this structure, the plurality of first transfer gate electrodes is adjusted between an ON state and an OFF state, whereby potential barriers under the plurality of first transfer gate electrodes adjacent to each other can easily make a separation between the pixels.

In the aforementioned structure including the first transfer gate electrodes and the second transfer gate electrode, the plurality of first transfer gate electrodes and the second transfer gate electrode are switched between an ON state and an OFF state a plurality of times during the imaging period. According to this structure, variation in dark currents generated in the regions under the plurality of first transfer gate electrodes and the second transfer gate electrode can be easily suppressed.

In the aforementioned structure including the first transfer gate electrodes and the second transfer gate electrode, at least one of the plurality of first transfer gate electrodes so arranged at the prescribed interval as to hold the boundary part of the plurality of pixels therebetween included in the transfer gate electrode is in an OFF state during the imaging period. According to this structure, at least one region of the regions under the plurality of first transfer gate electrodes adjacent to each other in the vicinity of the boundary part between the pixels is a potential barrier. Thus, it is possible to suppress that electrons stored in the adjacent pixels are mixed with each other.

The aforementioned structure including the first transfer gate electrodes and the second transfer gate electrode further comprises a light shielding film for making a separation between the pixels, provided between the boundary part of the pixels located between the first transfer gate electrodes and a boundary part of color regions of a color filter having a plurality of color regions provided above the pixel. According to this structure, it is possible to easily suppress that light incident on a pixel adjacent to a prescribed pixel is incident on the prescribed pixel.

In the solid-state image sensor according to the aforementioned aspect, the transfer gate electrode preferably includes a third transfer gate electrode located in the vicinity of the boundary part between the pixels, and the third transfer gate electrode is preferably always held in an OFF state during the imaging period. According to this structure, throughout the imaging period, a state in which the potential barrier is formed in a region under the third transfer gate electrode located in the vicinity of the boundary part between the pixels is held. Thus, it is possible to easily make a separation between the pixels.

In this case, the transfer gate electrode preferably further includes a plurality of fourth transfer gate electrodes so arranged inside the pixel as to be held between the third transfer gate electrodes, and the plurality of fourth transfer gate electrodes are preferably switched between an ON state and an OFF state during the imaging period. According to this structure, a potential well for storing electrons can be alternately formed in a region under a prescribed fourth transfer gate electrode and a region under a fourth transfer gate electrode other than the prescribed fourth transfer gate electrode in the same pixel during the imaging period. Thus, an averaging procedure can be performed for dark currents generated in the regions under a plurality of the fourth transfer gate electrodes in the same pixel during the imaging period, whereby variation in the dark currents generated in the regions under the plurality of fourth transfer gate electrodes can be suppressed.

In the aforementioned structure including the third transfer gate electrode and the fourth transfer gate electrodes, the plurality of fourth transfer gate electrodes are switched between an ON state and an OFF state a plurality of times during the imaging period. According to this structure, variation in the dark currents generated in the regions under the plurality of fourth transfer gate electrodes can be easily suppressed.

The aforementioned structure including the third transfer gate electrode and the fourth transfer gate electrodes preferably further comprises a color filter provided above the pixel and having a plurality of color regions, and a boundary part of the color regions of the color filter is preferably arranged above a region in which the third transfer gate electrode is located. According to this structure, the third transfer gate electrode in the imaging period has only a function of forming a potential barrier for making a separation between the pixels. Therefore, in a case where a light shielding film for making a separation between pixels are so provided as to cover the third transfer gate electrode (boundary part of the color regions of the color filter), it is possible to suppress that an exposing area of a region in which the electrons are stored is reduced.

In this case, the third transfer gate electrode is preferably arranged on a boundary part between the plurality of pixels. According to this structure, the third transfer gate electrode is always held in an OFF state during the imaging period, whereby a state in which the potential barrier is formed in the region under the third transfer gate electrode located in the vicinity of the boundary part between the pixels is held. Thus, it is possible to make a separation between the pixels

The aforementioned structure in which the third transfer gate electrode is arranged on the boundary part between a plurality of pixels preferably further comprises a light shielding film for making a separation between the pixels, provided between the third transfer gate electrode and the boundary part of the color regions of the color filter. According to this structure, it is possible to easily suppress that an exposing area of the region in which the electrons are stored is reduced.

In the aforementioned structure comprising the light shielding film for making a separation between the pixels, the light shielding film preferably has a width in a transfer direction substantially identical with that of the third transfer gate electrode and is preferably so arranged as to cover an overall upper surface of the third transfer gate electrode. According to this structure, it is possible to easily suppress that an exposing area of the region in which the electrons are stored is reduced, while suppressing that light incident on a pixel adjacent to a prescribed pixel is incident on the prescribed pixel.

The solid-state image sensor according to the aforementioned aspect preferably further comprises an image area including the transfer gate electrode and generating electrons during the imaging period and a storage area receiving the electrons transferred from the image area during the transfer period and storing the electrons. According to this structure, in the so-called frame transfer type solid-state image sensor comprising the image area and the storage area, it is possible to suppress generation of cross talk or a dark current, and to improve transfer efficiency of electrons (signal charge).

In this case, the image area is formed by stacking a first n-type semiconductor, a p-type semiconductor and a second n-type semiconductor. According to this structure, the first n-type semiconductor, the p-type semiconductor, and the second n-type semiconductor form a vertical overflow drain structure, whereby electrons serving as a dark current generated in the regions under the OFF-state transfer gate electrode by thermal excitation or the like can be pulled out to the first n-type semiconductor.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram showing an overall structure of a solid-state image sensor according to a first embodiment and a second embodiment of the present invention;

FIG. 2 is a plan view for illustrating a structure of an image area and a storage area of the solid-state image sensor according to the first embodiment shown in FIG. 1;

FIG. 3 is a sectional view for illustrating a structure of the image area of the solid-state image sensor according to the first embodiment shown in FIG. 1;

FIG. 4 is a voltage waveform diagram for illustrating operation in an imaging period and a transfer period of the solid-state image sensor according to the first embodiment of the present invention;

FIG. 5 is a potential diagram for illustrating the operation in the imaging period of the solid-state image sensor according to the first embodiment of the present invention;

FIG. 6 is a potential diagram for illustrating the operation in the transfer period of the solid-state image sensor according to the first embodiment of the present invention;

FIG. 7 is a plan view for illustrating a structure of an image area and a storage area of the solid-state image sensor according to the second embodiment of the present invention;

FIG. 8 is a sectional view for illustrating a structure of the image area of the solid-state image sensor according to the second embodiment of the present invention;

FIG. 9 is a voltage waveform diagram for illustrating operation in an imaging period and a transfer period of the solid-state image sensor according to the second embodiment of the present invention;

FIG. 10 is a potential diagram for illustrating the operation in the imaging period of the solid-state image sensor according to the second embodiment of the present invention; and

FIG. 11 is a potential diagram for illustrating the operation in the transfer period of the solid-state image sensor according to the second embodiment of the present invention;

### DESCRIPTION OF THE PREFERRED EMBODIMENTS

Embodiments of the present invention will be hereinafter described with reference to the drawings.

### First Embodiment

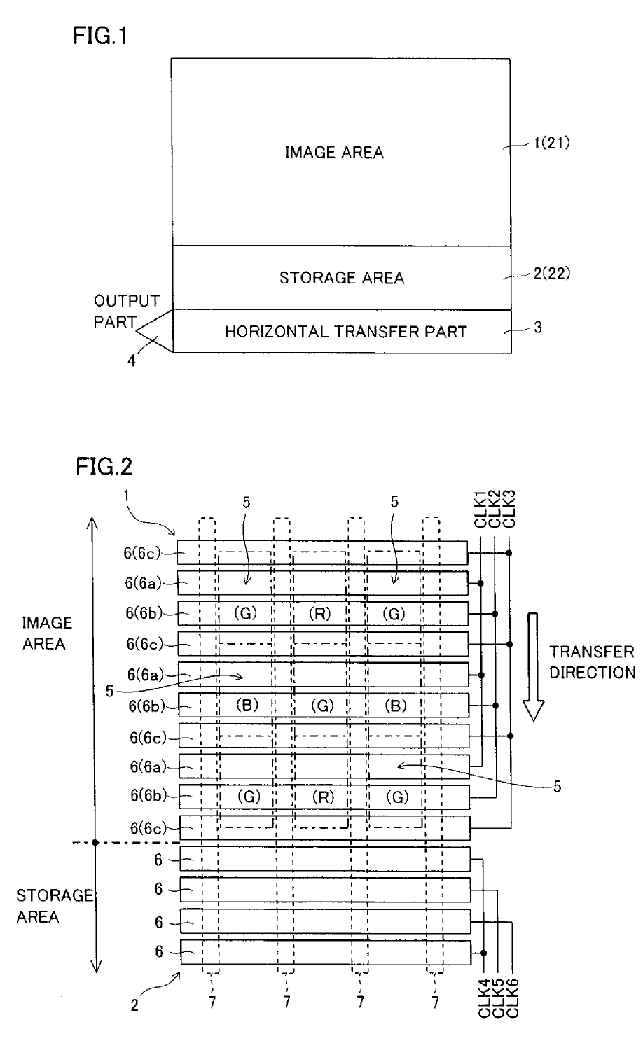

A structure of a solid-state image sensor according to a first embodiment will be described with reference to FIGS. 1 to 3.

The solid-state image sensor according to the first embodiment has a frame transfer structure comprising an image area 1, a storage area 2, a horizontal transfer part 3 and an output part 4 as shown in FIG. 1. The image area 1 has a structure in which a plurality of pixels 5 (region surrounded by an alternate long and short dash line) are arranged in the form of a matrix, as shown in FIG. 2. For ease of illustration, while FIG. 2 illustrates only nine pixels 5, nine or more pixels 5 are arranged in the form of a matrix in practice. The image area 1 (pixels 5) has a function of generating and storing electrons (signal charge) according to an amount of incident light and transferring the same to the storage area 2. The storage area 2 has a function of storing the electrons received from the image area 1 and transferring the same to the horizontal transfer part 3 as shown in FIG. 1. The horizontal transfer part 3 has a function of sequentially transferring the electrons received from the storage area 2 to the output part 4. The output part 4 has a function of outputting the electrons received from the horizontal transfer part 3 as an electric signal.

A plurality of transfer gate electrodes 6 are so provided in the image area 1 and the storage area 2 as to extend in a direction perpendicular to a transfer direction (row direction), as shown in FIG. 2. The plurality of transfer gate electrodes 6 are arranged at prescribed intervals in the transfer direction. While three-phase clock signals CLK1 to CLK3 for transferring electrons are supplied to the plurality of transfer gate electrodes 6 located on the image area 1, respectively, three-phase clock signals CLK4 to CLK6 for transferring electrons are supplied to the transfer gate electrodes 6 located on the storage area 2, respectively. The clock signals CLK1 to CLK6 are supplied to each of the plurality of transfer gate electrodes 6, whereby a potential well for storing and transferring electrons is formed on a region under each of the plurality of transfer gate electrodes 6. Pixel separation regions 7 for making a separation between the pixels 5 adjacent to each other in the row direction are so formed between the pixels 5 adjacent to each other in the row direction as to extend along the transfer direction to the storage area 2, respectively.

According to the first embodiment, in the image area 1, the transfer gate electrodes 6 include transfer gate electrodes 6a, 6b and 6c. Each transfer gate electrode 6c of the image area 1 is arranged on a boundary part in the transfer direction of the pixels 5 and the clock signal CLK3 is supplied to the transfer gate electrodes 6c. Each transfer gate electrodes 6a and 6b of the image area 1 are so arranged inside the pixel 5 as to be held by the transfer gate electrodes 6c, and the clock signals CLK1 and CLK2 are supplied to the transfer gate electrodes 6a and 6b, respectively. The transfer gate electrodes 6a and 6b are examples of the “fourth transfer gate electrode” in the present invention, the transfer gate electrodes 6c are examples of the “third transfer gate electrode” in the present invention.

According to the first embodiment, the three-phase clock signals CLK1 to CLK3 are controlled such that the transfer gate electrodes 6a and 6b are switched between an ON state and an OFF state in prescribed cycles and the transfer gate electrodes 6C are always held in an OFF state during an imaging period. The three-phase clock signals CLK1 to CLK3 and CLK4 to CLK6 are controlled such that all the transfer gate electrodes 6 of the image area 1 and the storage area 2 are switched between an ON state and an OFF state in prescribed cycles during a transfer period. The three-phase clock signals CLK1 to CLK3 are set such that an OFF-state voltage of the transfer gate electrodes 6 in the imaging period is lower than an OFF-state voltage of the transfer gate electrodes 6 in the transfer period. According to the first embodiment, the OFF-state voltage of the transfer gate electrodes 6 in the imaging period is set to about −8V, and the OFF-state voltage of the transfer gate electrodes 6 in the transfer period is set to about −5V.

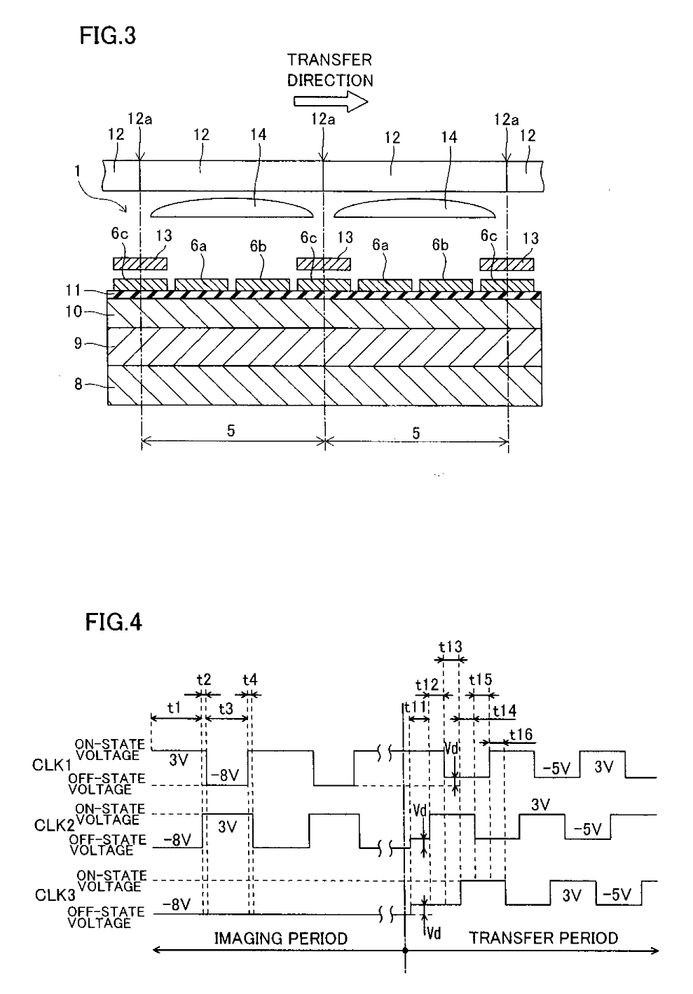

As shown in FIG. 3, in a cross-sectional structure of the image area 1 (pixels 5), a p-type silicon layer 9 and an n-type silicon layer 10 are sequentially formed on an n-type silicon substrate 8. The n-type silicon substrate 8 and the p-type silicon layer 9 are examples of the “first n-type semiconductor” and the “p-type semiconductor” in the present invention, respectively, and the n-type silicon layer 10 is an example of the “second n-type semiconductor” in the present invention. The aforementioned transfer gate electrodes 6a to 6c are formed above the n-type silicon layer 10 interposed a gate insulating film 11 consisting of SiO₂ film therebetween. According to the first embodiment, the n-type silicon substrate 8, the p-type silicon layer 9 and the n-type silicon layer 10 constitute a vertical overflow drain structure.

A Bayer pattern color filter 12 having a plurality of color regions corresponding to three primary colors of light (R (red), G (green) and B (blue)) are provided above the image area 1. In the color filter 12, the same color regions are arranged so as not to be adjacent to each other and the number of the color regions corresponding to the G (green) is twice the number of the color regions corresponding to the R (red) and the B (blue), as shown in FIG. 2.

According to the first embodiment, each of boundary parts 12a in a transfer direction of the color regions of the color filter 12 is so arranged above a region located on the transfer gate electrode 6c as to coincide with the boundary part in the transfer direction of the pixels 5, as shown in FIG. 3. Each of light shielding films 13 for making a separation between the pixels 5 are provided between the transfer gate electrode 6c and the boundary part 12a of the color regions of the color filter 12. Each light shielding film 13 has a width in the transfer direction identical with the transfer gate electrode 6c and is so arranged as to cover an overall upper surface of the transfer gate electrode 6c. Each of lenses 14 for condensing light is provided between the color filter 12 and the light shielding films 13 in one-to-one for the one pixel 5.

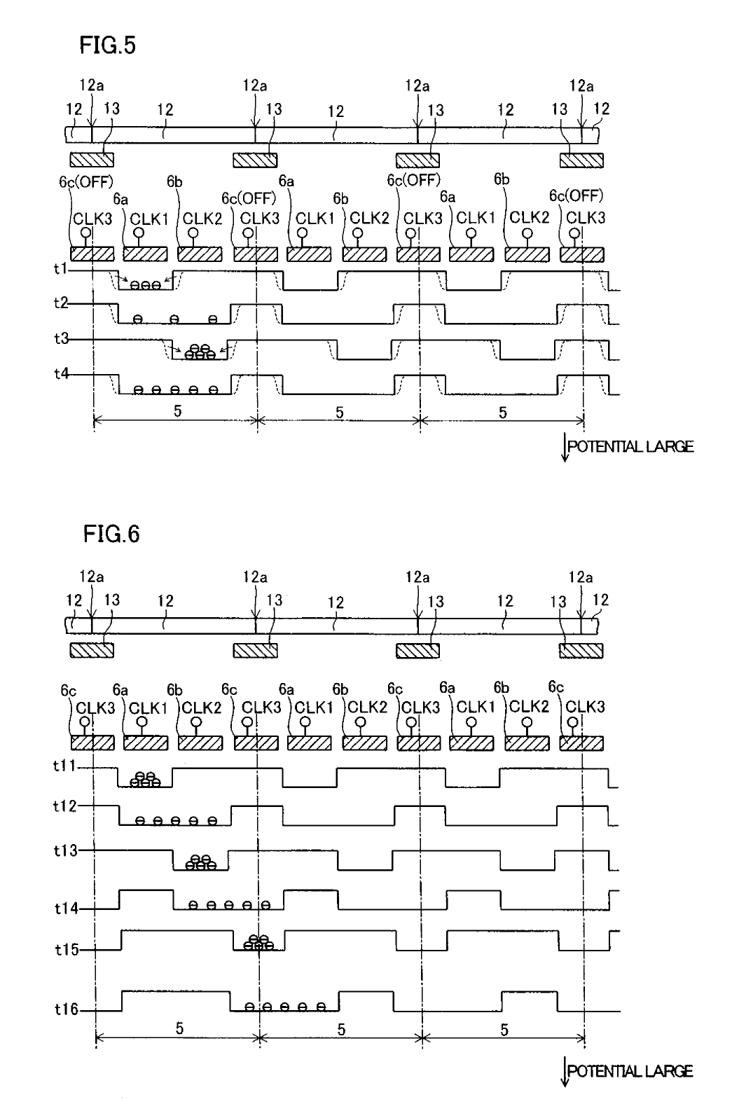

Operation in the imaging period and the transfer period of the solid-state image sensor according to the first embodiment will be now described with reference to FIGS. 1 to 6. While FIGS. 5 and 6 illustrates only operation of electrons stored under the transfer gate electrodes 6a, 6b and 6c of the pixel 5 at the far left thereof, electrons are also stored under the transfer gate electrodes 6a, 6b and 6c of the respective pixels 5 in practice, the operation of the electrons under the transfer gate electrodes of the respective pixels 5 are the same as that of the pixel 5 at the far left.

In the image area 1 shown in FIG. 3, light transmitted through the color filter 12 is condensed by each lens 14, whereby the light is incident on each pixel 5. Thus, the light transmitted through each of the corresponding color regions of the color filter 12 is photoelectrically converted to form electrons (signal charge) in each pixel 5.

At this time, the three-phase clock signals CLK1, CLK2 and CLK3 are set to about 3V, about −8V and about −8V, respectively (period t1 shown in FIG. 4). Accordingly, the transfer gate electrodes 6a, to which the clock signal CLK1 (about 3V) is supplied, are turned on, and the transfer gate electrodes 6b, to which the clock signal CLK2 (about −8V) is supplied, are turned off, as shown in FIG. 5. The transfer gate electrodes 6c, to which the clock signal CLK3 (about −8V) is supplied, are turned off. Thus, a potential well is formed in a region under each transfer gate electrode 6a, and electrons generated under each transfer gate electrode 6a by photoelectric conversion are stored in the potential well. Electrons serving as a dark current generated by thermal excitation or the like are also stored in the potential well formed in the region under each transfer gate electrode 6a, in addition to the electrons photoelectrically converted. The OFF-state voltage (about −8V) for turning off the transfer gate electrodes 6c in the imaging period is lower than the after-mentioned OFF-state voltage (about −5V) for turning off the transfer gate electrodes 6c in the transfer period.

A Potential (shown by a broken line in FIG. 5) of each potential well practically formed in the region under the transfer gate electrode 6a is gradually smaller from the region under the transfer gate electrode 6a towards the regions under the transfer gate electrodes 6b and 6c, and a larger portion of each potential expands to the regions under the transfer gate electrodes 6b and 6c. Therefore, not only the electrons generated in the region under each transfer gate electrode 6a by photoelectric conversion but also the electrons generated in the vicinity of the region under each transfer gate electrode 6a by photoelectric conversion are stored in the potential well practically formed in the region under the transfer gate electrode 6a. According to the first embodiment, the low OFF-state voltage (about −8V) is applied to the transfer gate electrodes 6c, whereby the larger portion of each potential of the potential well practically formed in the region under the transfer gate electrode 6a does not reach from a prescribed pixel 5 to other pixel 5 adjacent to the prescribed pixel 5 over the region under the OFF-state transfer gate electrode 6c. Therefore, according to the first embodiment, the region under each OFF-state transfer gate electrode 6c reliably function as a potential barrier for making a separation between the pixels 5.

According to the first embodiment, the low OFF-state voltage (about −8V) is applied to the transfer gate electrodes 6c, whereby a large number of holes generate on an interface between the n-type silicon layer 10 (see FIG. 3) and the gate insulating film 11 (see FIG. 3) under the OFF-state transfer gate electrodes 6c. Thus, it is possible to suppress that electrons serving as a dark current are excited in a conduction band through an interface state.

The clock signal CLK2 is changed from about −8V to about 3V in a state where the clock signals CLK1 and CLK3 are held at about 3V and about −8V respectively (period t2 shown in FIG. 4). Accordingly, the transfer gate electrodes 6a, to which the clock signal CLK1 (about 3V) is supplied, are held in an ON state, and the transfer gate electrodes 6b, to which the clock signal CLK2 (about 3V) is supplied, are changed to an ON state, as shown in FIG. 5. The transfer gate electrodes 6c, to which the clock signal CLK3 (about −8V) is supplied, are held in an OFF state. Thus, a continuous potential well is formed in the regions under each transfer gate electrodes 6a and 6b, and the electrons stored in the potential well formed in the region under each transfer gate electrode 6a in the period t1 are stored in the continuous potential well.

The clock signal CLK1 is changed from about 3V to about −8V in a state where the clock signals CLK2 and CLK3 are held at about 3V and about −8V respectively (period t3 shown in FIG. 4). Accordingly, as shown in FIG. 5, the transfer gate electrodes 6a, to which the clock signal CLK1 (about −8V) is supplied, are changed to an OFF state, and the transfer gate electrodes 6b, to which the clock signal CLK2 (about 3V) is supplied, are held in an ON state. The transfer gate electrodes 6c, to which the clock signal CLK3 (about −8V) is supplied, are held in an OFF state. Thus, a potential well is formed only in the region under each transfer gate electrode 6b, and the electrons stored in the potential well formed in the regions under each transfer gate electrodes 6a and 6b in the period t2 and electrons generated in the region under each transfer gate electrode 6b by photoelectric conversion, thermal excitation or the like (electrons serving as a dark current) are stored in the potential well.

The clock signal CLK1 is changed from about −8V to about 3V in a state where the clock signals CLK2 and CLK3 are held at about 3V and about −8V respectively (period t4 shown in FIG. 4). Accordingly, the transfer gate electrodes 6a, to which the clock signal CLK1 (about 3V) is supplied, are changed to an ON state, and the transfer gate electrodes 6b, to which the clock signal CLK2 (about 3V) is supplied, are held in an ON state, as shown in FIG. 5. The transfer gate electrodes 6c, to which the clock signal CLK3 (about −8V) is supplied, are held in an OFF state. Thus, a continuous potential well is formed in the regions under each transfer gate electrodes 6a and 6b, and the electrons stored in the potential well formed in the region under each transfer gate electrode 6b in the period t3 are stored in the continuous potential well.

Thereafter, operation similar to the operation performed in the aforementioned periods t1 to t4 is repeatedly performed. Specifically, the transfer gate electrodes 6a and 6b are switched between an ON state and an OFF state in prescribed cycles, and the transfer gate electrodes 6c are held in an OFF state.

During the transfer period, the three-phase clock signals CLK1, CLK2 and CLK3 are set to about 3V, about −5V and about −5V respectively (period t11 shown in FIG. 4). Accordingly, the transfer gate electrodes 6a, to which the clock signal CLK1 (about 3V) is supplied, are turned on, and the transfer gate electrodes 6b, to which the clock signal CLK2 (about −5V) is supplied, are turned off, as shown in FIG. 6. The transfer gate electrodes 6c, to which the clock signal CLK3 (about −5V) is supplied, are turned off. Thus, a potential well is formed in the region under each transfer gate electrode 6a, and the electrons stored in the imaging period are stored in the potential well. The OFF-state voltage (about −5V) for turning off the transfer gate electrodes 6c in the transfer period is higher than the aforementioned OFF-state voltage (about −8V) for turning off the transfer gate electrodes 6c in the imaging period by Vd (about 3V) (see FIG. 4).

According to the first embodiment, the high OFF-state voltage (about −5V) is applied to the transfer gate electrodes 6c, whereby an amount of holes generated in the region under each OFF-state transfer gate electrode 6c in the transfer period is reduced as compared with an amount of the aforementioned holes generated in the region under each OFF-state transfer gate electrode 6c in the imaging period. Therefore, when electrons are transferred to the region under each transfer gate electrode 6c, the probability of the recombination of the electrons and the holes is reduced.

The clock signal CLK2 is changed from about −5V to about 3V in a state where the clock signals CLK1 and CLK3 are held at about 3V and about −5V respectively (period t12 shown in FIG. 4). Accordingly, the transfer gate electrodes 6a, to which the clock signal CLK1 (about 3V) is supplied, are held in an ON state, and the transfer gate electrodes 6b, to which the clock signal CLK2 (about 3V) is supplied, are changed to an ON state, as shown in FIG. 6. The transfer gate electrodes 6c, to which the clock signal CLK3 (about −5V) is supplied, are held in an OFF state. Thus, a continuous potential well is formed in the region under each transfer gate electrodes 6a and 6b, and the electrons stored in the potential well formed in the regions under each transfer gate electrode 6a in the period t11 are stored in the continuous potential well.

The clock signal CLK1 is changed from about 3V to about −5V in a state where the clock signals CLK2 and CLK3 are held at about 3V and about −5V respectively (period t13 shown in FIG. 4). Accordingly, the transfer gate electrodes 6a, to which the clock signal CLK1 (about −5V) is supplied, are changed to an OFF state, and the transfer gate electrodes 6b, to which the clock signal CLK2 (about 3V) is supplied, are held in an ON state, as shown in FIG. 6. The transfer gate electrodes 6c, to which the clock signal CLK3 (about −5V) is supplied, are held in an OFF state. Thus, a potential well is formed only in the region under each transfer gate electrode 6b, and the electrons stored in the potential well formed in the regions under each transfer gate electrodes 6a and 6b in the period t12 are stored in the potential well.

The clock signal CLK3 is changed from about −5V to about 3V in a state where the clock signals CLK1 and CLK2 are held at about −5V and about 3V respectively (period t14 shown in FIG. 4). Accordingly, the transfer gate electrodes 6a, to which the clock signal CLK1 (about −5V) is supplied, are held in an OFF state, and the transfer gate electrodes 6b, to which the clock signal CLK2 (about 3V) is supplied, are held in an ON state, as shown in FIG. 6. The transfer gate electrodes 6c, to which the clock signal CLK3 (about 3V) is supplied, are changed to an ON state. Thus, a continuous potential well is formed in the regions under each transfer gate electrodes 6b and 6c, and the electrons stored in the potential well formed in the region under each transfer gate electrode 6b in the period t13 are stored in the continuous potential well.

The clock signal CLK2 is changed from about 3V to about −5V in a state where the clock signals CLK1 and CLK3 are held at about −5V and about 3V respectively (period t15 shown in FIG. 4). Accordingly, the transfer gate electrodes 6a, to which the clock signal CLK1 (about −5V) is supplied, are held in an OFF state, and the transfer gate electrodes 6b, to which the clock signal CLK2 (about −5V) is supplied, are changed to an OFF state, as shown in FIG. 6. The transfer gate electrodes 6c, to which the clock signal CLK3 (about 3V) is supplied, are held in an ON state. Thus, a potential well is formed only in the region under the transfer gate electrode 6c, and the electrons stored in the potential well formed in the regions under each transfer gate electrodes 6b and 6c in the period t14 are stored in the potential well.

The clock signal CLK1 is changed from about −5V to about 3V in a state where the clock signals CLK2 and CLK3 are held at about −5V and about 3V respectively (period t16 shown in FIG. 4). Accordingly, the transfer gate electrodes 6a, to which the clock signal CLK1 (about 3V) is supplied, are changed to an ON state, and the transfer gate electrodes 6b, to which the clock signal CLK2 (about −5V) is supplied, are held in an OFF state, as shown in FIG. 6. The transfer gate electrodes 6c, to which the clock signal CLK3 (about 3V) is supplied, are held in an ON state. Thus, a continuous potential well is formed in the region under each transfer gate electrodes 6c and 6a, and the electrons stored in the potential well formed in the region under each transfer gate electrode 6c in the period t15 are stored in the continuous potential well.

Thereafter, operation similar to the operation performed in the aforementioned periods t11 to t16 is repeatedly performed, whereby electrons stored in a prescribed pixel 5 in the imaging period are sequentially transferred to other pixel 5 adjacent to the prescribed pixel 5. Thus, the electrons of one frame (all pixels 5) stored in the image area 1 in the imaging period are transferred to the storage area 2 (see FIG. 2). In the storage area 2, the transfer gate electrodes 6 are driven in a similar manner to the aforementioned periods t11 to t16. The electrons stored in the storage area 2 are transferred to the horizontal transfer part 3 (see FIG. 1) for every one row, and the electrons in one row are output to the output part 4 (see FIG. 1).

According to the first embodiment, as hereinabove described, the OFF-state voltage (about −8V) of the transfer gate electrodes 6c located on the boundary parts between the respective pixels 5 in the imaging period is set lower than the OFF-state voltage (about −5V) of the transfer gate electrodes 6c located on the boundary parts between the respective pixels 5 in the transfer period, whereby the potential of the region under each OFF-state transfer gate electrode 6c located on the boundary part between the pixels 5 in the imaging period can be shallower than the potential of the region under each OFF-state transfer gate electrode 6c located on the boundary part between the pixels 5 in the transfer period. Thus, a height of a potential barrier of the region under each transfer gate electrode 6c located on the boundary part between the pixels 5 can be greater during the imaging period, whereby it is possible to suppress that electrons (signal charge) generated in other pixel 5 adjacent to a prescribed pixel 5 get over the potential barrier and are mixed into the prescribed pixel 5 during the imaging period. Consequently, generation of cross talk can be suppressed.

The OFF-state voltage (about −8V) of the transfer gate electrodes 6 in the imaging period is set lower than the OFF-state voltage (about −5V) of the transfer gate electrodes 6 in the transfer period, whereby an amount of holes generated in an interface between the n-type silicon layer 10 and the gate insulating film 11 under the OFF-state transfer gate electrodes 6 in the imaging period can be greater than an amount of holes generated in the interface between the n-type silicon layer 10 and the gate insulating film under the OFF-state transfer gate electrodes 6 in the transfer period. Thus, a large number of the holes exist in the interface between the n-type silicon layer 10 and the gate insulating film 11 under the OFF-state transfer gate electrodes 6 during the imaging period, whereby it is possible to suppress that electrons serving as a dark current are excited in the conduction band through the interface state. Consequently, generation of a dark current can be suppressed during the imaging period.

The OFF-state voltage (about −8V) of the transfer gate electrodes 6 in the imaging period is set lower than the OFF-state voltage (about −5V) of the transfer gate electrodes 6 in the transfer period, whereby an amount of the holes generated in the regions under the OFF-state transfer gate electrodes 6 in the transfer period can be fewer than an amount of the holes generated in the regions under the OFF-state transfer gate electrodes 6 in the imaging period. Thus, the probability of the recombination of the electrons and the holes can be reduced during the transfer period, whereby transfer efficiency of the electrons can be improved. Consequently, according to the first embodiment, generation of cross talk or a dark current can be suppressed, and transfer efficiency of electrons (signal charge) can be improved.

According to the first embodiment, as hereinabove described, when each transfer gate electrode 6c located on the boundary part between the pixels 5 is always held in an OFF state during the imaging period, whereby throughout the imaging period, a state in which the potential barrier is formed in the region under each transfer gate electrode 6c located on the boundary part between the pixels 5 is held. Thus, it is possible to easily make a separation between the respective pixels 5.

According to the first embodiment, as hereinabove described, the two transfer gate electrodes 6a and 6b arranged inside each pixel 5 are periodically switched between an ON state and an OFF state during the imaging period, whereby a potential well for storing electrons can be alternately formed in the region under the transfer gate electrode 6a and the region under the transfer gate electrode 6b in the same pixel 5 during the imaging period. Thus, an averaging procedure can be performed for dark currents generated in the regions under the transfer gate electrodes 6a and 6b in the same pixel 5 during the imaging period, whereby variation in the dark currents generated in the regions under the transfer gate 5 electrodes 6a and 6b can be suppressed.

According to the first embodiment, as hereinabove described, the boundary part 12a of the color regions of the color filter 12 are arranged above the region located on each transfer gate electrode 6c, whereby each transfer gate electrode 6c in the imaging period has only a function of forming a potential barrier for making a separation between the pixels 5. Therefore, even if the light shielding films 13 for making a separation between pixels are so provided as to cover the respective transfer gate electrodes 6c (boundary parts 12a of the respective color regions of the color filter 12), it is possible to suppress that exposing areas of the regions in which the electrons are stored are reduced.

According to the first embodiment, as hereinabove described, the so-called frame transfer type solid-state image sensor comprises the image area 1 including the transfer gate electrodes 6a, 6b and 6c and generating electrons during the imaging period, and the storage area 2 receiving electrons from the image area 1 during the transfer period and storing the electrons, whereby generation of cross talk or a dark current can be suppressed, and transfer efficiency of electrons (signal charge) can be improved.

According to the first embodiment, as hereinabove described, the image area 1 is formed by stacking the n-type silicon substrate 8, the p-type silicon layer 9 and the n-type silicon layer 10, whereby the n-type silicon substrate 8, the p-type silicon layer 9 and the n-type silicon layer 10 constitutes a vertical overflow drain structure. Thus, electrons serving as dark currents generated in the regions under the OFF-state transfer gate electrodes 6a, 6b and 6c by thermal excitation or the like can be pulled out to the n-type silicon substrate 8.

Experiments performed for confirming the aforementioned effects of suppressing generation of a dark current and effects of improving transfer efficiency of electrons (signal charge) will be now described.

First, in the experiment for confirming the effects regarding a dark current, an image is taken in the dark using the solid-state image sensor according to the aforementioned first embodiment (see FIGS. 1 to 3). At this time, the transfer gate electrodes 6a and 6b arranged inside the pixels 5 are switched between an ON state and an OFF state one time each. The transfer gate electrodes 6c arranged on the boundary parts between the respective pixels 5 are held in an OFF state. Output voltages of the respective pixels 5 are measured by setting the OFF-state voltage of the transfer gate electrodes 6 to −8V (first embodiment). As a comparative example, the output voltages of the respective pixels 5 are measured by setting the OFF-state voltage of the transfer gate electrodes 6 to −5V. As a result, variation in the output voltages of the respective pixels 5 in the dark in the first embodiment is reduced by about 35% as compared with variation in the output voltages of the respective pixels 5 in the dark in the comparative example.

From these results, in the first embodiment in which the OFF-state voltage of the transfer gate electrodes 6 is set to −8V, the generation of a dark current is suppressed as compared with the comparative example. Accordingly, variation in the output voltages of the respective pixels 5 is conceivably reduced. Specifically, the OFF-state voltage of the transfer gate electrodes 6 is set to −8V, whereby a larger number of holes in the interface between the n-type silicon layer 10 and the gate insulating film 11 under the OFF-state transfer gate electrodes 6 are generated as compared with a case where the OFF-state voltage of the transfer gate electrodes 6 is set to −5V. Thus, it is conceivable that excitation of electrons serving as a dark current is suppressed in the conduction band through the interface state.

In the experiment for confirming the effects regarding the transfer efficiency, an image is taken under an environment of a low-light intensity using the solid-state image sensor according to the aforementioned first embodiment (see FIG. 1 to 3). The transfer gate electrodes 6a to 6c are driven during the imaging period, in a similar manner to the aforementioned experiment for confirming a dark current. During the transfer period, the transfer gate electrodes 6 are switched between an ON state and an OFF state in prescribed cycles. An output voltage is measured for each of a plurality of the pixels 5 included in the same transfer line by setting the OFF-state voltage of the transfer gate electrodes 6 to −5V (first embodiment) in the transfer period. As an comparative example, an output voltage is measured for each of a plurality of the pixels 5 included in the same transfer line by setting the OFF-state voltage of the transfer gate electrodes 6 to −6V in the transfer period. As a result, variation in the output voltages for the plurality of the pixels 5 included in the same transfer lines in the first embodiment is reduced by about 45% as compared with variation in the output voltages for the plurality of the pixels 5 included in the same transfer lines in the comparative example.

From this result, in the first embodiment in which the OFF-state voltage of the transfer gate electrodes 6 in the transfer period is set to −5V, the recombination of electrons and holes in the transfer period is reduced. Accordingly, the variation in the output voltages for a plurality of pixels 5 included in the same transfer lines is conceivably reduced. Specifically, the OFF-state voltage of the transfer gate electrodes 6 in the transfer period is set to −5V, whereby an amount of holes generated in the regions under the OFF-state transfer gate electrodes 6 in the transfer period is fewer as compared with a case where the OFF-state voltage of the transfer gate electrodes 6 in the transfer period is set to −6V. Thus, the probability of the recombination of the electrons and the holes can be conceivably reduced.

### Second Embodiment

In a second embodiment, a structure of a solid-state image sensor in which transfer gate electrodes 26a and 26c are arranged on boundary parts in a transfer direction between respective pixels 25 will be now described with reference to FIGS. 1, 7 and 8, dissimilarly to the aforementioned first embodiment.

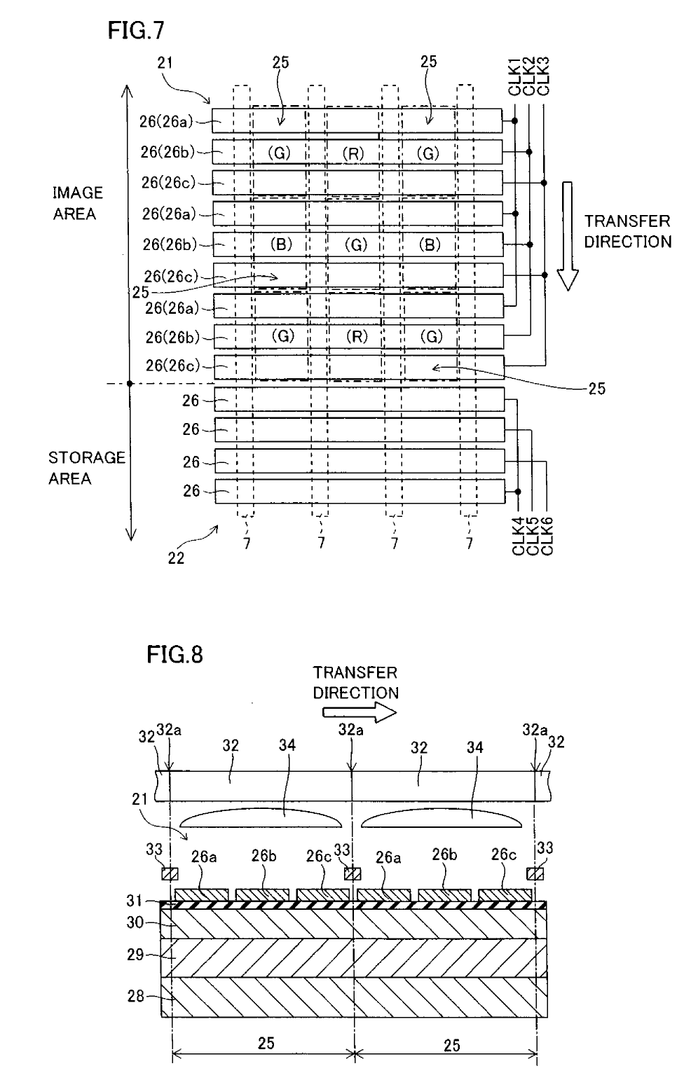

The solid-state image sensor according to the second embodiment has a frame transfer structure comprising an image area 21, a storage area 22, a horizontal transfer part 3 and an output part 4 as the first embodiment shown in FIG. 1. The image area 21 has a structure in which a plurality of pixels 25 (region surrounded by an alternate long and short dash line) are arranged in the form of a matrix, as shown in FIG. 7. For ease of illustration, while FIG. 7 illustrates only nine pixels 25, nine or more pixels 25 are arranged in the form of a matrix in practice. The image area 21 (pixels 25) has a function of generating and storing electrons (signal charge) according to an amount of incident light and transferring the same to the storage area 22. The storage area 22 has a function of storing the electrons received from the image area 21 and transferring the same to the horizontal transfer part 3 as shown in FIG. 1. The horizontal transfer part 3 has a function of sequentially transferring the electrons received from the storage area 2 to the output part 4. The output part 4 has a function of outputting the electrons received from the horizontal transfer part 3 as an electric signal.

A plurality of transfer gate electrodes 26 are so provided in the image area 21 and the storage area 22 as to extend in a direction perpendicular to a transfer direction (row direction), as shown in FIG. 7. The plurality of transfer gate electrodes 26 are arranged at prescribed intervals in the transfer direction respectively. While three-phase clock signals CLK1 to CLK3 for transferring electrons are supplied to the plurality of transfer gate electrodes 26 located on the image area 21, respectively, three-phase clock signals CLK4 to CLK6 for transferring electrons are supplied to the transfer gate electrodes 26 located on the storage area 22, respectively. The clock signals CLK1 to CLK6 are supplied to each of the plurality of transfer gate electrodes 26, whereby a potential well for storing and transferring electrons is formed in each of regions under the plurality of transfer gate electrodes 26. Pixel separation regions 7 for making a separation between the pixels 25 adjacent to each other in the row direction are so formed between the pixels 5 adjacent to each other in the row direction as to extend along the transfer direction to the storage area 22, respectively.

According to the second embodiment, in the image area 21, the transfer gate electrodes 26 include transfer gate electrodes 26a, 26b and 26c. Each transfer gate electrodes 26a and 26c of the image area 21 are so arranged at a prescribed interval as to hold a boundary line in the transfer direction of the pixels 25 therebetween, and the clock signals CLK1 and CLK3 are supplied to the transfer gate electrodes 26a and 26c respectively. Each transfer gate electrode 26b of the image area 21 is so arranged inside the pixel 25 as to be held by each transfer gate electrodes 26a and 26c, and the clock signal CLK2 is supplied to the transfer gate electrodes 26b. The transfer gate electrodes 26a and 26c are examples of the “first transfer gate electrode” in the present invention, the transfer gate electrodes 26b are examples of the “second transfer gate electrode” in the present invention.

According to the second embodiment, the three-phase clock signals CLK1 to CLK3 are controlled such that the transfer gate electrodes 26a, 26b and 26c are switched between an ON state and an OFF state in prescribed cycles during an imaging period. The three-phase clock signals CLK1 to CLK3 and CLK4 to CLK6 are controlled such that all the transfer gate electrodes 26 of the image area 21 and the storage area 22 are switched between an ON state and an OFF state in prescribed cycles during a transfer period. The three-phase clock signals CLK1 to CLK3 are set such that an OFF-state voltage of the transfer gate electrodes 26 in the imaging period is lower than an OFF-state voltage of the transfer gate electrodes 26 in the transfer period. According to the second embodiment, the OFF-state voltage of the transfer gate electrodes 26 in the imaging period is set to about −8V, and the OFF-state voltage of the transfer gate electrodes 26 in the transfer period is set to about −5V.

As shown in FIG. 8, in a cross-sectional structure of the image area 21 (pixels 25), a p-type silicon layer 29 and an n-type silicon layer 30 are sequentially formed on an n-type silicon substrate 28. The aforementioned transfer gate electrodes 26a to 26c are formed above the n-type silicon layer 30 interposed a gate insulating film 31 consisting of SiO₂ film therebetween. According to the second embodiment, the n-type silicon substrate 28, the p-type silicon layer 29 and the n-type silicon layer 30 constitute a vertical overflow drain structure.

A Bayer pattern color filter 32 having a plurality of color regions corresponding to three primary colors of light (R (red), G (green) and B (blue)) are provided above the image area 21. In the color filter 32, the same color regions are arranged so as not to be adjacent to each other and the number of the color regions corresponding to the G (green) is twice the number of the color regions corresponding to the R (red) and the B (blue), as shown in FIG. 7.

According to the second embodiment, each of boundary parts 32a in a transfer direction of the color regions of the color filter 32 is so arranged at a prescribed interval as to coincide with the boundary part in the transfer direction of the pixels 25 and as to be held between the transfer gate electrodes 26a and 26c, as shown in FIG. 8. Each of light shielding films 33 are provided between a boundary part of pixels 25 held between the transfer gate electrodes 26a and 26c and the boundary part 32a of the color regions of the color filter 32 having a plurality of color regions provided above the pixel 25. Each of lenses 34 for condensing light is provided between the color filter 32 and the light shielding films 33 in one-to-one for the one pixel 25.

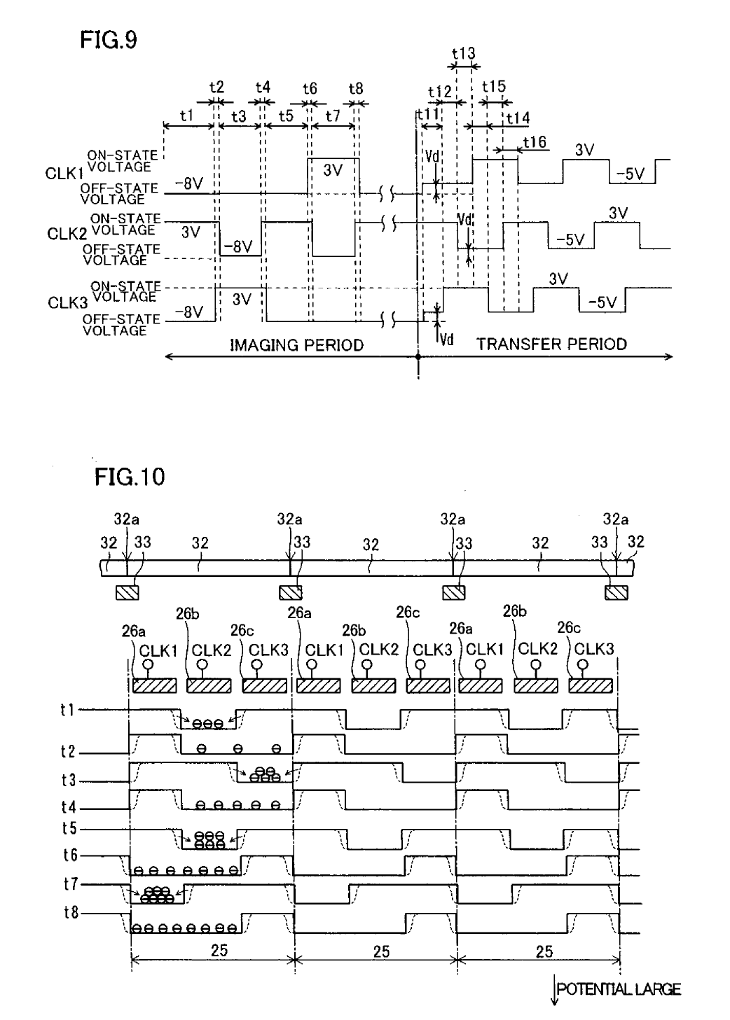

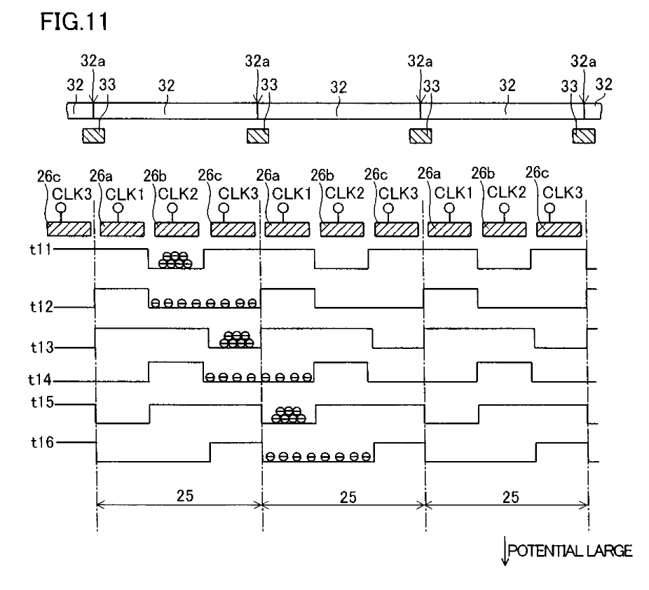

Operation in the imaging period and the transfer period of the solid-state image sensor according to the second embodiment will be now described with reference to FIGS. 1 and 7 to 11. While FIGS. 10 and 11 illustrate only operation of electrons stored under the transfer gate electrodes of the pixel 25 at the far left thereof electrons are also stored under the transfer gate electrodes 26a, 26b and 26c of the respective pixels 25 in practice, the operation of the electrons under the transfer gate electrodes 26a, 26b and 26c of the respective pixels 25 are the same as that of the pixel 25 at the far left.

In the image area 21 shown in FIG. 8, light transmitted through the color filter 32 is condensed by each lens 34, whereby the light is incident on each pixel 25. Thus, the light transmitted through each of the corresponding color regions of the color filter 32 is photoelectrically converted to form electrons (signal charge) in each pixel 25.

At this time, the three-phase clock signals CLK1, CLK2 and CLK3 are set to about −8V, about 3V and about −8V, respectively (period t1 shown in FIG. 9). Accordingly, the transfer gate electrodes 26a, to which the clock signal CLK1 (about −8V) is supplied, are turned off, and the transfer gate electrodes 26b, to which the clock signal CLK2 (about 3V) is supplied, are turned on, as shown in FIG. 10. The transfer gate electrodes 26c, to which the clock signal CLK3 (about −8V) is supplied, are turned off. Thus, a potential well are formed in a region under each transfer gate electrode 26b, and electrons generated under each transfer gate electrode 26b by photoelectric conversion are stored in the potential well. Electrons serving as a dark current generated by thermal excitation are also stored in the potential well formed in the region under each transfer gate electrodes 26b, in addition to the electrons photoelectrically converted. The OFF-state voltage (about −8V) for turning off the transfer gate electrodes 26a, 26b and 26c in the imaging period is lower than the after-mentioned OFF-state voltage (about −5V) for turning off the transfer gate electrodes 26a, 26b and 26c in the transfer period.

A Potential (shown by a broken line in FIG. 10) of each potential well practically formed in the region under the transfer gate electrode 26b is gradually smaller from the region under the transfer gate electrode 26b towards the regions under the transfer gate electrodes 26a and 26c, and a larger portion of each potential expands to the regions under the transfer gate electrodes 26a and 26c. Therefore, not only the electrons generated in the region under each transfer gate electrode 26b by photoelectric conversion but also the electrons generated in the vicinity of the region under each transfer gate electrode 26b by photoelectric conversion are stored in the potential well practically formed in the region under each transfer gate electrode 26b. According to the second embodiment, the low OFF-state voltage (about −8V) is applied to the transfer gate electrodes 26a and 26c, whereby the larger portion of each potential of the potential well practically formed in the region under the transfer gate electrode 26b does not reach from a prescribed pixel 25 to other pixel 25 adjacent to the prescribed pixel 25 over the regions under the OFF-state transfer gate electrodes 26a and 26c. Therefore, according to the second embodiment, the regions under each OFF-state transfer gate electrodes 26a and 26c reliably function as potential barriers for making a separation between the pixels 25.

According to the second embodiment, the low OFF-state voltage (about −8V) is applied to the transfer gate electrodes 26a and 26c, whereby a large number of holes generate on an interface between the n-type silicon layer 30 (see FIG. 8) and the gate insulating film 31 (see FIG. 8) under the OFF-state transfer gate electrodes 26a and 26c. Thus, it is possible to suppress that electrons serving as a dark current are excited in a conduction band through an interface state.

The clock signal CLK3 is changed from about −8V to about 3V in a state where the clock signals CLK1 and CLK2 are held at about −8V and about 3V respectively (period t2 shown in FIG. 9). Accordingly, the transfer gate electrodes 26a, to which the clock signal CLK1 (about −8V) is supplied, are held in an OFF state, and the transfer gate electrodes 26b, to which the clock signal CLK2 (about 3V) is supplied, are held in an ON state, as shown in FIG. 10. The transfer gate electrodes 26c, to which the clock signal CLK3 (about 3V) is supplied, are changed to an ON state. Thus, a continuous potential well is formed in each regions under each transfer gate electrodes 26b and 26c, and the electrons stored in the potential well formed in the region under each transfer gate electrode 26b in the period t1 are stored in the continuous potential well.

The clock signal CLK2 is changed from about 3V to about −8V in a state where the clock signals CLK1 and CLK3 are held at about −8V and about 3V respectively (period t3 shown in FIG. 9). Accordingly, as shown in FIG. 10, the transfer gate electrodes 26a, to which the clock signal CLK1 (about −8V) is supplied, are held in an OFF state, and the transfer gate electrodes 26b, to which the clock signal CLK2 (about −8V) is supplied, are changed to an OFF state. The transfer gate electrodes 26c, to which the clock signal CLK3 (about 3V) is supplied, are held in an ON state. Thus, a potential well is formed only in the region under each transfer gate electrode 26c, and the electrons stored in the potential well formed in the regions under each transfer gate electrodes 26b and 26c in the period t2 and electrons generated in the region under each transfer gate electrode 26c by photoelectric conversion, thermal excitation or the like (electrons serving as a dark current) are stored in the potential well.

The clock signal CLK2 is changed from about −8V to about 3V in a state where the clock signals CLK1 and CLK3 are held at about −8V and about 3V respectively (period t4 shown in FIG. 9). Accordingly, the transfer gate electrodes 26a, to which the clock signal CLK1 (about −8V) is supplied, are held in an OFF state, and the transfer gate electrodes 26b, to which the clock signal CLK2 (about 3V) is supplied, are changed to an ON state, as shown in FIG. 10. The transfer gate electrodes 26c, to which the clock signal CLK3 (about 3V) is supplied, are held in an ON state. Thus, a continuous potential well is formed in the regions under each transfer gate electrodes 26b and 26c, and the electrons stored in the potential well formed in the region under each transfer gate electrode 26c in the period t3 are stored in the continuous potential well.

The clock signal CLK3 is changed from about 3V to about −8V in a state where the clock signals CLK1 and CLK2 are held at about −8V and about 3V respectively (period t5 shown in FIG. 9). Accordingly, the transfer gate electrodes 26a, to which the clock signal CLK1 (about −8V) is supplied, are held in an OFF state, and the transfer gate electrodes 26b, to which the clock signal CLK2 (about 3V) is supplied, are held in an ON state, as shown in FIG. 10. The transfer gate electrodes 26c, to which the clock signal CLK3 (about −8V) is supplied, are changed to an OFF state. Thus, a potential well is formed only in the region under each transfer gate electrode 26b, and the electrons stored in the potential well formed in the regions under each transfer gate electrodes 26b and 26c in the period t4 and electrons generated in the region under each transfer gate electrode 26b by photoelectric conversion, thermal excitation or the like (electrons serving as a dark current) are stored in the potential well.

The clock signal CLK1 is changed from about −8V to about 3V in a state where the clock signals CLK2 and CLK3 are held at about 3V and about −8V respectively (period t6 shown in FIG. 9). Accordingly, the transfer gate electrodes 26a, to which the clock signal CLK1 (about 3V) is supplied, are changed to an ON state, and the transfer gate electrodes 26b, to which the clock signal CLK2 (about 3V) is supplied, are held in an ON state, as shown in FIG. 10. The transfer gate electrodes 26c, to which the clock signal CLK3 (about −8V) is supplied, are held in an OFF state. Thus, a continuous potential well is formed in the regions under each transfer gate electrodes 26a and 26b, and the electrons stored in the potential well formed in the region under each transfer gate electrode 26b in the period t5 are stored in the continuous potential well.

The clock signal CLK2 is changed from about 3V to about −8V in a state where the clock signals CLK1 and CLK3 are held at about 3V and about −8V respectively (period t7 shown in FIG. 9). Accordingly, the transfer gate electrodes 26a, to which the clock signal CLK1 (about 3V) is supplied, are held in an ON state, and the transfer gate electrodes 26b, to which the clock signal CLK2 (about −8V) is supplied, are changed to an OFF state, as shown in FIG. 10. The transfer gate electrodes 26c, to which the clock signal CLK3 (about −8V) is supplied, are held in an OFF state. Thus, a potential well is formed only in the region under each transfer gate electrode 26a, and the electrons stored in the potential well formed in the regions under each transfer gate electrodes 26a and 26b in the period t6 and electrons generated in the region under each transfer gate electrode 26a by photoelectric conversion, thermal excitation or the like (electrons serving as a dark current) are stored in the potential well.

The clock signal CLK2 is changed from about −8V to about 3V in a state where the clock signals CLK1 and CLK3 are held at about 3V and about −8V respectively (period t8 shown in FIG. 9). Accordingly, the transfer gate electrodes 26a, to which the clock signal CLK1 (about 3V) is supplied, are held in an ON state, and the transfer gate electrodes 26b, to which the clock signal CLK2 (about 3V) is supplied, are changed to an ON state, as shown in FIG. 10. The transfer gate electrodes 26c, to which the clock signal CLK3 (about −8V) is supplied, are held in an OFF state. Thus, a continuous potential well is formed in the regions under each transfer gate electrodes 26a and 26c, and the electrons stored in the potential well formed in the region under each transfer gate electrode 26a in the period t7 are stored in the continuous potential well.

Thereafter, operation similar to the operation performed in the aforementioned periods t1 to t8 is repeatedly performed. Specifically, the transfer gate electrodes 26a, 26b and 26c are switched between an ON state and an OFF state in prescribed cycles.

During the transfer period, the three-phase clock signals CLK1, CLK2 and CLK3 are set to about −5V, about 3V and about −5V respectively (period t11 shown in FIG. 9). Accordingly, the transfer gate electrodes 26a, to which the clock signal CLK1 (about −5V) is supplied, are turned off, and the transfer gate electrodes 26b, to which the clock signal CLK2 (about 3V) is supplied, are turned on, as shown in FIG. 11. The transfer gate electrodes 26c, to which the clock signal CLK3 (about −5V) is supplied, are turned off. Thus, a potential well is formed in the region under each transfer gate electrode 26b, and the electrons stored in the imaging period are stored in the potential well. The OFF-state voltage (about −5V) for turning off the transfer gate electrodes 26a, 26b and 26c in the transfer period is higher than the aforementioned OFF-state voltage (about −8V) for turning off the transfer gate electrodes 26a, 26b and 26c in the imaging period by Vd (about 3V) (see FIG. 9).

According to the second embodiment, the high OFF-state voltage (about −5V) is applied to the transfer gate electrodes 26a, 26b and 26c, whereby an amount of holes generated in the region under the OFF-state transfer gate electrodes 26a, 26b and 26c in the transfer period is reduced as compared with an amount of the aforementioned holes generated in the regions under the OFF-state transfer gate electrodes 26a, 26b and 26c in the imaging period. Therefore, when electrons are transferred to the regions under the transfer gate electrodes 26a, 26b and 26c, the probability of the recombination of the electrons and the holes is reduced.

The clock signal CLK3 is changed from about −5V to about 3V in a state where the clock signals CLK1 and CLK2 are held at about −5V and about 3V respectively (period t12 shown in FIG. 9). Accordingly, the transfer gate electrodes 26a, to which the clock signal CLK1 (about −5V) is supplied, are held in an OFF state, and the transfer gate electrodes 26b, to which the clock signal CLK2 (about 3V) is supplied, are held in an ON state, as shown in FIG. 11. The transfer gate electrodes 26c, to which the clock signal CLK3 (about 3V) is supplied, are held in an ON state. Thus, a continuous potential well is formed in the regions under each transfer gate electrodes 26b and 26c, and the electrons stored in the potential well formed in the region under each transfer gate electrode 26b in the period t11 are stored in the continuous potential well.

The clock signal CLK2 is changed from about 3V to about −5V in a state where the clock signals CLK1 and CLK3 are held at about −5V and about 3V respectively (period t13 shown in FIG. 9). Accordingly, the transfer gate electrodes 26a, to which the clock signal CLK1 (about −5V) is supplied, are held in an OFF state, and the transfer gate electrodes 26b, to which the clock signal CLK2 (about −5V) is supplied, are changed to an OFF state, as shown in FIG. 11. The transfer gate electrodes 26c, to which the clock signal CLK3 (about 3V) is supplied, are held in an ON state. Thus, a potential well is formed only in the region under each transfer gate electrode 26c, and the electrons stored in the potential well formed in the regions under each transfer gate electrodes 26b and 26c in the period t12 are stored in the potential well.

The clock signal CLK1 is changed from about −5V to about 3V in a state where the clock signals CLK2 and CLK3 are held at about −5V and about 3V respectively (period t14 shown in FIG. 9). Accordingly, the transfer gate electrodes 26a, to which the clock signal CLK1 (about 3V) is supplied, are changed to an ON state, and the transfer gate electrodes 26b, to which the clock signal CLK2 (about −5V) is supplied, are held in an OFF state, as shown in FIG. 11. The transfer gate electrodes 26c, to which the clock signal CLK3 (about 3V) is supplied, are held in an ON state. Thus, a continuous potential well is formed in the regions under each transfer gate electrodes 26a and 26c, and the electrons stored in the potential well formed in the region under each transfer gate electrode 26c in the period t13 are stored in the potential well.

The clock signal CLK3 is changed from about 3V to about −5V in a state where the clock signals CLK1 and CLK2 are held at about 3V and about −5V respectively (period t15 shown in FIG. 9). Accordingly, the transfer gate electrodes 26a, to which the clock signal CLK1 (about 3V) is supplied, are held in an ON state, and the transfer gate electrodes 26b, to which the clock signal CLK2 (about −5V) is supplied, are held in an OFF state, as shown in FIG. 11. The transfer gate electrodes 26c, to which the clock signal CLK3 (about −5V) is supplied, are changed to an OFF state. Thus, a potential well is formed only in the region under each transfer gate electrode 26a, and the electrons stored in the potential well formed in the regions under each transfer gate electrodes 26a and 26c in the period t14 are stored in the potential well.

The clock signal CLK2 is changed from about −5V to about 3V in a state where the clock signals CLK1 and CLK3 are held at about 3V and about −5V respectively (period t16 shown in FIG. 9). Accordingly, the transfer gate electrodes 26a, to which the clock signal CLK1 (about 3V) is supplied, are held in an ON state, and the transfer gate electrodes 26b, to which the clock signal CLK2 (about 3V) is supplied, are changed to an ON state, as shown in FIG. 11. The transfer gate electrodes 26c, to which the clock signal CLK3 (about −5V) is supplied, are held in an OFF state. Thus, a continuous potential well is formed in the regions under each transfer gate electrodes 26a and 26b, and the electrons stored in the potential wells formed in the regions under each transfer gate electrode 26a in the period t15 are stored in the continuous potential well.

Thereafter, operation similar to the operation performed in the aforementioned periods t11 to t16 is repeatedly performed, whereby electrons stored in a prescribed pixel 25 in the imaging period are sequentially transferred to other pixel 25 adjacent to the prescribed pixel 25. Thus, the electrons of one frame (all pixels 25) stored in the image area 21 in the imaging period are transferred to the storage area 22 (see FIG. 7). In the storage area 22, the transfer gate electrodes 26 are driven in a similar manner to the aforementioned periods t11 to t16. The electrons stored in the storage area 22 are transferred to the horizontal transfer part 3 (see FIG. 1) for every one row, and the electrons in one row are output to the output part 4 (see FIG. 1).

According to the second embodiment, as hereinabove described, the transfer gate electrodes 26 include the transfer gate electrodes 26a and 26c located in the vicinity of the boundary parts between the pixels 25 and the transfer gate electrodes 26b so arranged as to be held between the transfer gate electrodes 26a and 26c, and the transfer gate electrodes 26a, 26b and 26c are switched between an ON state and an OFF state during the imaging period, whereby during the imaging period, the potential wells for storing electrons can be formed in the regions under the transfer gate electrodes 26a, 26b and 26c in the same pixel 25 respectively. Thus, an averaging procedure can be performed for dark currents generated in the regions under the transfer gate electrodes 26a, 26b and 26c in the same pixel 5 during the imaging period, whereby variation in the dark currents generated in the regions under the transfer gate electrodes 26a, 26b and 26c can be suppressed.

According to the second embodiment, as hereinabove described, at least one of each transfer gate electrodes 26a and 26c adjacent to each other in the vicinity of the boundary part between pixels 25 included in the transfer gate electrode 26 is turned off during the imaging period, whereby at least one region under each transfer gate electrodes 26a and 26c adjacent to each other in the vicinity of the boundary part between the pixels 25 is a potential barrier. Thus, it is possible to suppress that electrons stored in the adjacent pixels 25 are mixed with each other.

According to the second embodiment, as hereinabove described, each of the light shielding films 33 for making a separation between the pixels 25 is provided between the boundary part of the transfer gate electrodes 26a and 26c of the adjacent pixels 25 and the boundary part 32a of the color regions of the color filter 32 having a plurality of color regions provided above the pixel 25, whereby it is possible to easily suppress that light incident upon each pixel 25 adjacent to a prescribed pixel 25 is mixed into the prescribed pixel 25.

Other effects of the second embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the two transfer gate electrodes for forming the potential well in the imaging period are arranged in each pixel in the aforementioned first embodiment, the present invention is not restricted to this but one transfer gate electrode or at least three transfer gate electrodes for forming the potential well in the imaging period may be alternatively arranged in each pixel.

While stored electrons are transferred in the same pixel by switching the two transfer gate electrodes arranged inside each pixel between an ON state and an OFF state in prescribed cycles during the imaging period in the aforementioned first embodiment, the present invention is not restricted to this but at least one transfer gate electrode arranged inside each pixel may be alternatively always held in an ON state during the imaging period.

While the OFF-state voltage in the imaging period is set to about −8V and the OFF-state voltage in the transfer period is set to about −5V in the aforementioned first and second embodiments, the present invention is not restricted to this as long as the OFF-state voltage in the imaging period is lower than the OFF-state voltage in the transfer period. For example, the OFF-state voltages in the imaging period and the transfer period may be set to 0V and 2V (positive voltage) respectively. The OFF-state voltages in the imaging period and the transfer period are set to a negative voltage and a positive voltage respectively.

While the one transfer gate electrode 26b is held between the transfer gate electrodes 26a and 26c located in the vicinity of the boundary parts between the pixels in the aforementioned second embodiment, the present invention is not restricted to this but the two or more transfer gate electrodes 26b between the transfer gate electrodes 26a and 26c may be alternatively arranged.

What is claimed is:

1. A solid-state image sensor comprising:
a plurality of pixels; and
a transfer gate electrode arranged in each of said plurality of pixels, wherein
an OFF-state voltage of said transfer gate electrode located at least in the vicinity of a boundary part between said pixels in an imaging period is lower than an OFF-state voltage of said transfer gate electrode located at least in the vicinity of said boundary part between said pixels in a transfer period.

2. The solid-state image sensor according to claim 1, wherein
a position in which a potential well for storing electrons is formed is switched between a region under a prescribed transfer gate electrode and a region under a transfer gate electrode other than said region under said prescribed transfer gate electrode during an imaging period, using at least two transfer gate electrodes among a plurality of said transfer gate electrodes.

3. The solid-state image sensor according to claim 2, wherein
said position in which said potential well for storing electrons is formed is switched between said region under said prescribed transfer gate electrode and said region under said transfer gate electrode other than said region under said prescribed transfer gate electrode a plurality of times during said imaging period.

4. The solid-state image sensor according to claim 1, wherein
said transfer gate electrode includes a plurality of first transfer gate electrodes located in the vicinity of said boundary part between said pixels and a second transfer gate electrode so arranged as to be held between said plurality of first transfer gate electrodes, and
said plurality of first transfer gate electrodes and said second transfer gate electrode are switched between an ON state and an OFF state during said imaging period.

5. The solid-state image sensor according to claim 4, wherein
said plurality of first transfer gate electrodes are so arranged at a prescribed interval as to hold said boundary part of said plurality of pixels therebetween.

6. The solid-state image sensor according to claim 4, wherein
said plurality of first transfer gate electrodes and said second transfer gate electrode are switched between an ON state and an OFF state a plurality of times during said imaging period.

7. The solid-state image sensor according to claim 4, wherein,
at least one of said plurality of first transfer gate electrodes so arranged at said prescribed interval as to hold said boundary part of said plurality of pixels therebetween, included in said transfer gate electrode is in an OFF state during said imaging period.

8. The solid-state image sensor according to claim 4, further comprising:
a light shielding film for making a separation between said pixels, provided between said boundary part of said pixels located between said first transfer gate electrodes and a boundary part of color regions of a color filter having a plurality of color regions provided above said pixel.

9. The solid-state image sensor according to claim 1, wherein
said transfer gate electrode includes a third transfer gate electrode located in the vicinity of said boundary part between said pixels, and
said third transfer gate electrode is always held in an OFF state during said imaging period.

10. The solid-state image sensor according to claim 9, wherein
said transfer gate electrode further includes a plurality of fourth transfer gate electrodes so arranged inside said pixel as to be held between said third transfer gate electrodes, and
said plurality of fourth transfer gate electrodes are switched between an ON state and an OFF state during said imaging period.

11. The solid-state image sensor according to claim 10, wherein
said plurality of fourth transfer gate electrodes are switched between an ON state and an OFF state a plurality of times during said imaging period.

12. The solid-state image sensor according to claim 9, further comprising:
a color filter provided above said pixel and having a plurality of color regions, wherein
a boundary part of said color regions of said color filter is arranged above a region in which said third transfer gate electrode is located.

13. The solid-state image sensor according to claim 12, wherein
said third transfer gate electrode is arranged on a boundary part between said plurality of pixels.

14. The solid-state image sensor according to claim 13, further comprising:
a light shielding film for making a separation between said pixels, provided between said third transfer gate electrode and said boundary part of said color regions of said color filter.

15. The solid-state image sensor according to claim 14, wherein
said light shielding film has a width in a transfer direction substantially identical with that of said third transfer gate electrode and is so arranged as to cover an overall upper surface of said third transfer gate electrode.

16. The solid-state image sensor according to claim 1, further comprising:
an image area including said transfer gate electrode and generating electrons during said imaging period; and
a storage area receiving said electrons transferred from said image area during said transfer period and storing said electrons.

17. The solid-state image sensor according to claim 16, wherein
said image area is formed by stacking a first n-type semiconductor, a p-type semiconductor and a second n-type semiconductor.
